(19) United States
(12) Patent Application Publication
(10) Pub. No.: US 2013/0048045 A1
(43) Pub. Date: Feb. 28, 2013

(54) HEAT RECOVERY SYSTEM FOR PYROMETALLURGICAL VESSEL USING THERMOELECTRIC/THERMOMAGNETIC DEVICES

(71) Applicants: Ingo Bayer, London (GB); Bruce Ringsby Olmstead, The Willows (ZA)

(72) Inventors: Ingo Bayer, London (GB); Bruce Ringsby Olmstead, The Willows (ZA)

(73) Assignee: BHP BILLITON ALUMINIUM TECHNOLOGIES LIMITED, Jersey (GB)

(21) Appl. No.: 13/581,583

(22) PCT Filed: Mar. 9, 2011
(86) PCT No.: PCT/EP2011/053537

§ 371 Date: Nov. 2, 2012

(30) Foreign Application Priority Data
Mar. 10, 2010 (AU) 2010900996
Mar. 19, 2010 (AU) 2010901176

(51) Int. Cl. H01L 37/04; F27D 17/00

(52) U.S. Cl. 136/201; 266/160; 136/205

(57) ABSTRACT

A method and apparatus for harvesting waste thermal energy from a pyrometallurgical vessel (1) and converting that energy to direct electrical current, the method including deriving and controlling a primary fluid flow (103) from a primary heat exchanger (10) associated with the pyrometallurgical vessel (1), providing a secondary heat exchanger (12) physically displaced from the pyrometallurgical vessel (1) which exchanges heat between the primary fluid flow (103) from the primary heat exchanger (10) and a secondary fluid flow (104). The secondary heat exchanger (12) has at least one thermoelectric or magneto-thermoelectric device having two operationally-opposed sides, the operationally-opposed sides being in thermal communication with the primary and secondary fluid flows (103,104) respectively. A temperature difference is maintained between the two operationally-opposed sides of the thermoelectric or magneto-thermoelectric device and electrical energy is generated from the temperature differential. The pyrometallurgical vessel preferably generates a magnetic field (14) in the region surrounding the pyrometallurgical vessel (1) and the secondary heat exchanger (12) having at least one magneto-thermoelectric device is positioned physically displaced from but within the magnetic field (14) surrounding the pyrometallurgical vessel such that the direction of temperature gradient across the secondary heat exchanger is oriented normally to the maximum principal direction of the magnetic field (14) and electrical energy is generated from the temperature differential and magnetic field via the Nernst effect or magneto-thermoelectric effects.

### FIELD OF THE INVENTION

This invention relates to a method and apparatus for the recovery of waste heat from a pyrometallurgical vessel which may or may not generate a magnetic field during operation.

### BACKGROUND OF THE INVENTION

Pyrometallurgical processes, which in the context of this invention refer to the thermal treatment of minerals, metallic ores and concentrates to bring about physical and/or chemical transformations in order to enable recovery of valuable metals, include but are not limited to drying, calcining, roasting, smelting, fuming and refining (including electrolytic processes). Processes at temperatures above about 100° C., have significant energy requirements, used for example, to maintain elevated temperatures. Some specific examples of pyrometallurgical processes having large energy demands include ore sintering, ore reduction/refining, and metal reduction/refining. These energy needs are often provided for by fossil fuel combustion or electricity. In most cases, the energy is not used as efficiently as desirable. A significant loss of energy is through diffuse heat transferred away from the process as part of its operation.

In a particular instance, during reduction of aluminium oxide (alumina) to form aluminium in electrolytic cells, only about 40% of the total power consumed is actually used by the reduction process. Much of the remainder of the power is used to maintain the temperature of the process environment, but once generated this heat is naturally lost to the process by heat flux through the sides of the reduction vessel. A modern aluminium smelting operation may lose as much as 300 MW of energy due to the continual need to maintain a high temperature process environment.

The generation of significant quantities of waste heat is not confined to aluminium electrolysis cells as many pyrometallurgical processes require a high temperature thermal environment within the processing unit. Many high temperature pyrometallurgical vessels further require control of the internal temperatures and heat flow at the vessel wall to maintain protective freeze linings to cover the refractory components within the pyrometallurgical vessel walls. Thus, while the invention may be described with reference to aluminium electrolysis cells, it is applicable to a wide range of pyrometallurgical vessels used for high temperature treatment and refining of ores, and extraction of valuable metals and their chemical compounds such as their oxides at temperatures generally in excess of 100° C. This invention may also find application in the conversion of energy contained in the off-gases of these pyrometallurgical processes.

Although in most instances this waste heat is currently expelled to the vessel surroundings without further treatment, it is also possible to capture this heat by means of a heat transfer medium operating within or near the refractory linings of the vessel. An example of such art is presented in PCT/AU2005/001617, wherein it is taught that by providing fluid ducts adjacent to the inside shell surface of an aluminium reduction cell, heat can be extracted from the cell by a heat transfer medium, such as air, flowing through those ducts. In PCT/AU2005/001617, it is also taught that this heated fluid may then be used to further transfer the heat captured within the reduction vessel to other applications.

Ducts may further be constructed within the sidewall refractory slabs of the reduction vessel, also with the purpose of removing heat from the vessel by means of a heat transfer fluid passing though those ducts. As ducts within the sidewall refractory slabs of the vessel are closer to the heat generated by the reduction process, it is expected that not only would greater temperatures be accessed by the heat transfer fluid (thereby heating it to a greater extent than would be possible just within the vessel shell), but the greater amount of heat available for removal by the fluid would also facilitate improved control of the temperatures at the inner surface of the refractory lining.

The general aspects of removal of heat from the refractory lining of a pyrometallurgical vessel by means of a heat transfer fluid travelling in various ducts within or near the lining represent an established art. It is common to all such constructions however that the fluid travelling within the ducts is heated as it passes through the ducts. This invention considers the further treatment of that heated fluid so as to harvest the heat carried within the flowing fluid.

The quantity of heat transferred to a coolant flowing in a heated duct can be controlled by varying the mass flow rate of that coolant within the duct. As the ducts are constructed adjacent to or within the lining components of the pyrometallurgical vessel, changes in the temperature of the coolant by means of varying its mass flow rate will also cause a variation in the temperature of the lining components themselves. Control over this variation in the lining temperatures can be provided by comparison of the outlet coolant temperature with a reference temperature which would drive changes to valve settings or the motive force provided by the fan, pump or other motive device.

Waste heat harvested from the shell or linings of a reduction vessel may be used in the generation of electrical energy. Such heat as may be harvested from the pyrometallurgical vessel may, if conditions are suitable, be used in the generation of electricity by such well-known constructions as a Rankine cycle based turbine set. Alternatively, the waste heat, when passed through thermoelectric semiconductor materials may be used to generate direct electrical current by means of the Seebeck effect.

As discussed above however a heat transfer fluid, such as air, which is heated in ducts or other devices built into the inner part of the refractory lining of the pyrometallurgical vessel will not only contain an increased heat load, but will also present that load at a higher temperature. These hotter conditions are beneficial for the conversion of thermal energy to electrical energy.

Rather than further processing this thermal energy directly on or within the pyrometallurgical vessel, significant benefits are seen in transferring the hot heat transfer fluid to an external secondary heat exchanger displaced from the pyrometallurgical vessel wherein thermoelectric devices are used to convert the thermal energy to electrical current. Transfer of the hot heat transfer fluid from the pyrometallurgical vessel lining to the external heat exchanger may be accomplished by any means known to those versed in the art. One example of such transfer path might take the form of suitably insulated pipes or tubes.

Conversion of thermal energy to electrical energy by means of thermoelectric devices relies upon the development of a temperature gradient across the thermoelectric elements within those devices. While the hot side of these devices may be effectively heated by the hot heat transfer fluid collected from the pyrometallurgical vessel lining, any of a number of efficient means may be used to cool the cold side of the devices. Cooling techniques might include the use of gaseous or liquid heat transfer fluids applied to the cold side of the thermoelectric devices, or the use of two-phase evaporative cooling technologies. In regard to pyrometallurgical vessels and in particular reduction/refining vessels, neither of these cooling techniques could be considered for use if the thermoelectric devices were connected intimately to the pyrometallurgical vessel shell, due to insufficient separation of electrical potentials or connection to earth as well as the added danger of explosive phase changes in the fluids if they were to come in contact with the hot liquid metal and electrolyte contents of the reduction vessel.

Suitable orientation of the thermoelectric elements in a magnetic field can beneficially enhance the energy conversion of the devices. This enhancement of thermoelectric device performance may be attributed variously to the Nernst (or Nernst-Ettingshausen) effect, or to the magnetic sensitivity of some of the common thermoelectric materials themselves. In the instance of the Nernst effect, this enhancement of thermoelectric device performance arises in the mutually-orthogonal orientation of the temperature gradient, the magnetic field and the intended flow of the generated electrical current.

It is common that pyrometallurgical process vessels, and in particular aluminium reduction vessels are substantially surrounded by busbars which carry the substantial electrical currents required for the aluminium electrolysis process. The currents carried by these busbars clearly give rise to significant magnetic fields and positioning the secondary heat exchanger advantageously within those magnetic fields will thus, by means of the Nernst effect or other material responses, enhance the electrical output from the secondary heat exchanger. Such thermoelectric devices are referred to herein as magneto-thermoelectric devices and materials used therein as magneto-thermoelectric materials. In the particular instance of aluminium reduction cells, one advantageous location for placing the secondary heat exchanger would thus be in close proximity to the large busbars which surround the vessel.

Reference to any prior art in the specification is not, and should not be taken as, an acknowledgment or any form of suggestion that this prior art forms part of the common general knowledge in Australia or any other jurisdiction or that this prior art could reasonably be expected to be ascertained, understood and regarded as relevant by a person skilled in the art.

### SUMMARY OF THE INVENTION

There is significant waste energy expelled from pyrometallurgical vessels, typically in the form of diffuse waste heat. While for practical reasons, this waste heat must be collected on or preferably within the process vessel shell, processing and conversion of the waste heat to more usable forms, notably electrical current, within or immediately around the pyrometallurgical vessel imposes several inefficiencies upon the conversion process. This is particularly true in the case in which thermoelectric or magneto-thermoelectric devices are used to convert the thermal energy to electrical energy.

It is highly desirable for reasons of efficiency to operate thermoelectric devices across as large a temperature gradient as possible. Where the temperature of the hot side of the thermoelectric devices is limited by the temperature of a heat transfer fluid which is placed in contact with the process vessel shell or lining components, it is advantageous to cool the cold side of the devices to as great an extent as is possible. Effective cooling practices for the cold side of the thermoelectrics might involve the use of liquid or two phase coolants. For reasons of risk around explosive phase changes which can easily occur when liquids come into contact with liquid metal, these coolants cannot be used in close proximity to the pyrometallurgical vessel. The use of these more efficient cooling techniques thus requires removal of the conversion phase of the energy recovery to a location displaced from the immediate proximity of the pyrometallurgical vessel.

Additionally, suitable orientation of thermoelectric and magneto-thermoelectric devices in a magnetic field enhances the performance of these devices, due to the Nernst effect as well as a magnetic field dependence of certain of the properties of the thermoelectric materials themselves. The most suitable magnetic fields for enhancing the device performance are not generally located in the same areas as is most suitable for collecting the waste heat hence the need (in addition to safety concerns around explosion risks) to displace the secondary heat exchanger from the immediate proximity of the pyrometallurgical vessel.

The applicants are of the view that considerable gains in efficiency, safety and practical application can be achieved where the conversion phase of heat recovery from pyrometallurgical process vessels is separated from the collection phase of the recovery process. The collection phase of the process is contained within a primary heat exchanger, which is used to collect waste heat in a gaseous heat transfer fluid, such as air. The conversion phase of the heat recovery is then contained within a separate secondary heat exchanger containing thermoelectric elements which convert the collected thermal energy to electrical energy.

The electrical current generated by the secondary heat exchanger is not necessarily intended at this stage to represent part of the current flow which is used directly in the pyrometallurgical process. It instead represents direct current electrical energy which is recovered from heat expelled from the pyrometallurgical vessels and may be applied to any purpose for which electricity is normally used in a pyrometallurgical processing plant. In the particular instance of an aluminium smelter, this additionally-generated electrical current might be used to supplement the current used in the electrolysis process or it might be used to power some of the smelter auxiliary equipment, such as fans or compressors.

Accordingly, in one aspect of the present invention, there is provided a method for harvesting waste thermal energy from a pyrometallurgical vessel and converting that energy to direct electrical current, the method including
deriving and controlling a primary fluid flow from a primary heat exchanger associated with the pyrometallurgical vessel, the primary heat exchanger extracting heat from the pyrometallurgical vessel and transferring the heat to the primary fluid flow in a controlled manner;
providing a secondary heat exchanger which exchanges heat between the primary fluid flow and a secondary fluid flow,
providing within the secondary heat exchanger at least one thermoelectric or magneto-thermoelectric device having two operationally-opposed sides, the operationally-opposed sides being in thermal communication with the primary and secondary fluid flows respectively;
locating the secondary heat exchanger in a position physically displaced from the pyrometallurgical vessel;
establishing or maintaining a temperature difference between the two operationally-opposed sides of the at least one thermoelectric or magneto-thermoelectric device and generating electrical energy from the temperature differential; and
collecting the electrical current generated by the thermoelectric device.

Preferably the pyrometallurgical vessel generates a magnetic field in the region surrounding the pyrometallurgical vessel from electrical current used to operate the vessel, the magnetic field having a maximum principal direction component. The method further comprises the positioning of the secondary heat exchanger having at least one magneto-thermoelectric device in a position physically displaced from but within the magnetic field surrounding the pyrometallurgical vessel, and
establishing or maintaining a temperature difference between the two operationally-opposed sides of the magneto-thermoelectric device, wherein the direction of temperature gradient being oriented normally to the maximum principal direction of the magnetic field and generating electrical energy from the temperature differential and magnetic field via the Nernst effect or magneto-thermoelectric effects; and
collecting the electrical current generated by the magneto-thermoelectric device.

The primary fluid is preferably gaseous. In a preferred form the secondary fluid is gaseous, liquid or a duel phase fluid and most preferably the secondary fluid is liquid

In the above preferred form of the invention, the method may also include the steps of controlling the primary fluid flow rate and preferably the secondary fluid flow rate to control the temperature gradient across the thermoelectric or magneto-thermoelectric device. The primary fluid flow and preferably secondary fluid flow rates are controlled to maximise the temperature gradient across the thermoelectric or magneto-thermoelectric device while maintaining optimal heat flows through the pyrometallurgical vessel linings.

Accordingly, in a further aspect, there is provided an apparatus for the conversion of waste thermal energy from a pyrometallurgical vessel to electrical energy, the pyrometallurgical vessel having a primary heat exchanger which extracts heat from the vessel and produces a primary heat transfer fluid, the apparatus comprising
a secondary heat exchanger engagable with the primary heat exchanger of the pyrometallurgical vessel to receive the primary heat transfer fluid, the secondary heat exchanger being displaced from the pyrometallurgical vessel
a thermoelectric or magneto-thermoelectric device having a first operational side and a second operational side and having at least one thermoelectric or magneto-thermoelectric element capable of converting a temperature gradient between the first operational side and the second operational side into electrical energy;
the secondary heat exchanger supporting the thermoelectric or magneto-thermoelectric device in a fixed position so that the first operational side is able to thermally communicate with the primary heat transfer fluid from the primary heat exchanger and the second operational side is able to thermally communicate with a secondary coolant to establish the temperature differential between the first operational side and the second operational side of the thermoelectric or magneto-thermoelectric device to generate electrical energy.

Preferably, the pyrometallurgical vessel is surrounded by a magnetic field generated from the input operating electrical power to the pyrometallurgical vessel, the magnetic field having a maximum principal direction component, and the secondary heat exchanger supporting at least the magneto-thermoelectric device in a fixed position so the maximum principal magnetic field component is positioned normally to the direction of the temperature gradient developed between the first operational side and the second operational side of the magneto-thermoelectric device.

The above apparatus may further comprise at least one control device and a valve located on a cold side conduit conducting the primary heat transfer fluid into the primary heat exchanger; the at least one control device being located on a hot side conduit conducting the heated primary heat exchange fluid from the primary heat exchanger. The temperature of fluid in the cold side of the primary heat exchanger equates approximately with the temperature of the fluid in the hot side of the secondary heat exchanger. In order to control the magnitude of the temperature of fluid entering the secondary heat exchanger, the at least one control device and the cold side valve communicate to regulate the mass flow rate of coolant through the hot side conduits of the primary heat exchanger.

In the above apparatus the primary fluid is preferably gaseous and the secondary fluid may be gaseous, liquid or a dual phase fluid and most preferably the secondary fluid is liquid

The quantity or mass flow rate of the primary heat transfer fluid passing into the secondary heat exchanger may be adjusted by means of valves as required to provide for control of the heat leaving the pyrometallurgical vessel and to assist in optimising the conversion of current in the thermoelectric elements contained in the secondary heat exchanger.

The invention may be retrofitted to an existing pyrometallurgical vessel or it may be incorporated into a new structure having a primary fluid flow from a primary heat exchanger to a secondary heat exchanger which uses thermoelectric and/or magneto-thermoelectric devices for the conversion of waste heat to electrical power.

In a further aspect the invention provides a pyrometallurgical vessel utilising as part of its operation
a primary heat exchanger located within the lining of the pyrometallurgical vessel which extracts heat from the vessel and heats a primary heat transfer fluid,
a secondary heat exchanger engagable with the primary heat exchanger of the pyrometallurgical vessel to receive the primary heat transfer fluid, the secondary heat exchanger being physically displaced from the pyrometallurgical vessel; and
a thermoelectric or magneto-thermoelectric device supported in a fixed position by the secondary heat exchanger, the thermoelectric or magneto-thermoelectric device having a first operational side and a second operational side and having at least one thermoelectric or magneto-thermoelectric element capable of converting a temperature gradient between the first operational side and the second operational side into electrical energy; the first operational side being in thermal communication with the primary heat transfer fluid from the primary heat exchanger and the second operational side being in thermal communication with a secondary coolant to establish the temperature differential between the first operational side and the second operational side of the thermoelectric or magneto-thermoelectric device to generate electrical energy.

The above pyrometallurgical vessel may be surrounded by a magnetic field generated from input operating electrical power to the pyrometallurgical vessel, the magnetic field having a maximum principal direction component, and the secondary heat exchanger supports at least the magneto-thermoelectric device so the maximum principal magnetic field component is positioned normally to the direction of the temperature gradient developed between the first operational side and the second operational side of the magneto-thermoelectric device.

In each of the abovementioned embodiments of this invention, the secondary heat exchanger provides as its primary output an electrical current which is routed by means of suitable wires, cables, busbars or other means of transmission to service other smelter electrical requirements, including, but not be limited to, process electrical power or power to operate smelter auxiliary equipment.

As used herein, except where the context requires otherwise, the term “comprise” and variations of the term, such as “comprising”, “comprises” and “comprised”, are not intended to exclude further additives, components, integers or steps.

### BRIEF DESCRIPTION OF THE DRAWINGS/FIGURES

FIG. 1 illustrates the energy flows and equipment required for a thermoelectric heat exchanger located externally to the pyrometallurgical vessel as described in this invention.

### DETAILED DESCRIPTION OF THE EMBODIMENTS

The invention will now be described with reference to its general use as a means of enhancing the efficiency of harvesting waste energy generated by pyrometallurgical process vessels. These efficiency improvements may relate to facilitating the safe use of heat transfer fluids having a higher heat capacity than the commonly-used gaseous fluids as a means of cooling the cold side of a thermoelectric array. These improvements may, where applicable (as for instance in equipment used for the electrolytic reduction of aluminium), relate to facilitating access to magnetic fields which would improve the recovery efficiency of thermoelectric devices by means of the Nernst effect or by material property improvements within the thermoelectric materials which may also be induced by the presence of a suitably-oriented magnetic field.

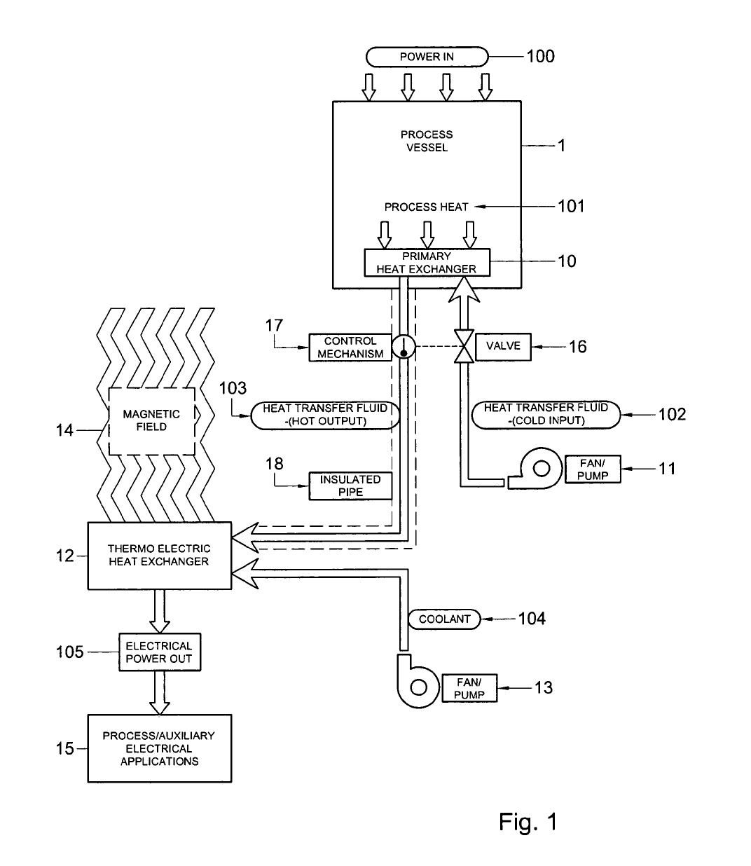

As shown in FIG. 1, pyrometallurgical process vessels (1) require a thermal energy input, designated as “Power In” (100) to develop the thermal and/or electrical conditions under which the conversion of ores to valuable metals may occur. These conditions not only relate to the maintenance of a high temperature environment around the pyrometallurgical reaction, but may also require an electrical potential to aid in reducing the various oxides which are placed in the pyrometallurgical vessel. The input energy (100) to the pyrometallurgical vessel (1) may be thermal and/or electrical in nature, but at least part of that energy, indicated as process heat (101) is used to develop and maintain a steady high-temperature environment, as would be required for the pyrometallurgical reactions to occur.

The pyrometallurgical process vessel (1) may be constructed in such a way as to contain within it a primary heat exchanger (10) which may be used to capture at least a portion of the process heat (101). This primary heat exchanger may be placed for instance in direct contact with the reacting ores and their reducing chemical reagents, thereby extracting heat. In another instance the primary heat exchanger may be constructed adjacent to or as part of the refractory lining of the pyrometallurgical vessel (1) with the intent of harvesting thermal energy from the heat fluxes through the walls of the vessel.

Irrespective of its location within the pyrometallurgical vessel (1), the primary heat exchanger (10) serves to pass the heat it collects from the pyrometallurgical vessel (1) to a heat transfer fluid. This heat transfer fluid is driven through the heat exchanger by a fan, pump or motive device (11), entering the primary heat exchanger (10) as a cold input fluid (102). This fluid is heated in the primary heat exchanger (10), and leaves as the hot output fluid (103). The heated output fluid (103) is conveyed from the primary heat exchanger (10) to a secondary heat exchanger (12) by means of heavily-insulated tubes or pipes (18). Although the primary heat transfer process is shown in FIG. 1 in terms of an open fluid circuit, it is also possible that the primary heat transfer loop be operated as a closed circuit, in which the output fluid is cooled and recirculated continuously by the fan or pump through the primary heat exchanger (10).

The temperature of the heat transfer fluid as well as that of the material through which the heat transfer ducts pass may be controlled by varying the mass flow rate of the coolant. Variation of the mass flow rate is accomplished by one or more valves (16) placed in the cold inlet heat transfer fluid lines (102). The flow through the valves is controlled and adjusted by instrumentation (17) comparing the temperature of the hot output heat transfer fluid (103) with a known reference value and relaying a control signal from that instrumentation (17) to the valves (16). This temperature control not only ensures an optimal temperature for the input heat transfer fluid (103) to the thermoelectric heat exchanger, but also caters for the occurrence and control of local temperature irregularities in the material surrounding the heat transfer ducts in the primary heat exchanger (10).

The separate thermoelectric heat exchanger (12) comprises the heart of this invention. Located at a distance from the external shell of the pyrometallurgical vessel, the thermoelectric heat exchanger (12) receives the hot heat transfer fluid (103) and processes it to convert the thermal energy contained in the hot fluid to an output direct current electrical power (105).

Although many variants are known to those versed in the art, the basic inner workings of a thermoelectric generator are common throughout all variations. The basic requirement for such a generator is a thermoelectric element which is heated on one side and cooled on its reverse side thereby creating the thermal gradient driving the development of an electrical current in the thermoelectric material. Suitable thermoelectric materials are disclosed in PCT/EP2009/061661 and PCT/EP2009/061639, the whole contents of which are hereby incorporated by reference. In the present invention, the hot side of the thermoelectric devices is heated by the hot output heat transfer fluid (103), and the cold side of the thermoelectric elements is cooled by an externally-supplied coolant (104).

The external placement of the thermoelectric heat exchanger (12) permits the use of a wide variety of efficient fluids to be used as the coolant (104). The high risk associated with insufficient separation of electrical potentials or connection to earth as well as the added danger of explosive phase changes in the fluids if they were to come in contact with the hot liquid metal and electrolyte contents of the reduction vessel usually precludes the use of liquids or dual-phase coolants within or in close contact with pyrometallurgical process vessels. External placement of the thermoelectric heat exchanger (12) significantly mitigates this risk, so that the coolant (104) could be selected from any of a wide range of efficient cooling fluids, such as water. Of course air or other gases could also be used as a coolant (104), although at lesser efficiency than would be achieved with a liquid.

A fan, pump or other suitable motive device (13) is used to drive the coolant through the cold side of the thermoelectric heat exchanger. Although FIG. 1 shows the coolant circuit to be open in nature, it is also possible that a closed circuit could be used in which the coolant may be re-cooled after it has passed through the thermoelectric heat exchanger. It would then be recirculated through the thermoelectric heat exchanger by the fan, pump or other motive device (13).

Although not present in all pyrometallurgical operations, a magnetic field (14) may be present around and in the general neighbourhood of the pyrometallurgical vessel. This magnetic field is typically associated with high electrical currents passing through busbars surrounding the vessel and supplying the input power (100) for the pyrometallurgical vessel (1). Such intense magnetic fields commonly pervade the area around the electrolytic process vessels used in the production of aluminium.

It is well known by those well-versed in the art that thermoelectric materials may be beneficially enhanced if they are correctly oriented within an intense magnetic field. Additionally, there is an alternative class of magneto-thermoelectric materials which develop an electric current in the presence of orthogonal magnetic and heat flux fields. This magneto-thermoelectric current generation is known variously as the Nernst or Nernst-Ettingshausen effect. Suitable orientation of the secondary heat exchanger (12) within the magnetic field (14) further enhances the electrical current output (105) of the secondary heat exchanger (12). Suitable magneto-thermoelectric materials are disclosed in PCT/EP2009/061639, the whole contents of which are hereby incorporated by reference

The electrical power output (105) is obtained solely from the secondary heat exchanger (12) and does not comprise any part of the normal smelter or factory incoming current. This newly-generated electrical current (105) is thus available as an additional energy source for process or auxiliary electrical applications (15).

It will be understood that the invention disclosed and defined in this specification extends to all alternative combinations of two or more of the individual features mentioned or evident from the text or drawings. All of these different combinations constitute various alternative aspects of the invention.

1. A method for harvesting waste thermal energy from a pyrometallurgical vessel (1) and converting that energy to direct electrical current, the method including
deriving and controlling a primary fluid flow from a primary heat exchanger (10) associated with the pyrometallurgical vessel (1), the primary heat exchanger (10) extracting heat from the pyrometallurgical vessel (1) and transferring the heat to the primary fluid flow in a controlled manner;
providing a secondary heat exchanger (12) which exchanges heat between the primary fluid flow and a secondary fluid flow,
providing within the secondary heat exchanger (12) at least one thermoelectric or magneto-thermoelectric device having two operationally-opposed sides, the operationally-opposed sides being in thermal communication with the primary and secondary fluid flows respectively;
locating the secondary heat exchanger (12) in a position displaced from the pyrometallurgical vessel (1);
establishing or maintaining a temperature difference between the two operationally-opposed sides of the at least one thermoelectric or magneto-thermoelectric device and generating electrical energy from the temperature differential; and
collecting the electrical current (105) generated by the thermoelectric device.

2. The method of claim 1 wherein
the pyrometallurgical vessel (1) generates a magnetic field in the region surrounding the pyrometallurgical vessel (1) from electrical current used to operate the vessel, the magnetic field (14) having a maximum principal direction component;
positioning the secondary heat exchanger (12) having at least one magneto-thermoelectric device within the magnetic field (14) surrounding the pyrometallurgical vessel (1);
establishing or maintaining a temperature difference between the two operationally-opposed sides of the magneto-thermoelectric thermoelectric device, the direction of temperature gradient being oriented normally to the maximum principal direction of the magnetic field (14) and generating electrical energy from the temperature differential and magnetic field via the Nernst effect or magneto-thermoelectric effects; and
collecting the electrical current (105) generated by the thermoelectric device.

3. The method of claim 1 wherein the primary fluid is gaseous.

4. The method of claim 1 wherein the secondary fluid is gaseous, liquid or a dual phase fluid.

5. The method of claim 4 wherein the secondary fluid is liquid.

6. The method of claim 1 further comprising the steps of controlling the primary fluid flow rate and the secondary fluid flow rate to control the temperature gradient across the thermoelectric or magneto-thermoelectric device.

7. The method of claim 6 wherein the primary fluid flow and secondary fluid flow rates are controlled to maximise the temperature gradient.

8. An apparatus for the conversion of waste thermal energy from a pyrometallurgical vessel (1) to electrical energy, the pyrometallurgical vessel (1) having a primary heat exchanger (10) which extracts heat from the vessel (1) and produces a heated primary heat transfer fluid, the apparatus comprising
a secondary heat exchanger (12) engagable with the primary heat exchanger of the pyrometallurgical vessel (1) to receive the primary heat transfer fluid, the secondary heat exchanger (12) being displaced from the pyrometallurgical vessel (1);
a thermoelectric or magneto-thermoelectric device having a first operational side and a second operational side and having at least one thermoelectric or magneto-thermoelectric element capable of converting a temperature gradient between the first operational side and the second operational side into electrical energy;
the secondary heat exchanger (12) supporting the thermoelectric or magneto-thermoelectric device in a fixed position so that the first operational side is able to thermally communicate with the primary heat transfer fluid from the primary heat exchanger (10) and the second operational side is able to thermally communicate with a secondary coolant to establish the temperature differential between the first operational side and the second operational side of the thermoelectric or magneto-thermoelectric device to generate electrical energy (105).

9. The apparatus of claim 8 wherein
the pyrometallurgical vessel (1) is surrounded by a magnetic field (14) generated from input operating electrical power (100) to the pyrometallurgical vessel (1), the magnetic field (14) having a maximum principal direction component; and
the secondary heat exchanger (12) supports at least the magneto-thermoelectric device in a fixed position so the maximum principal magnetic field component is positioned normally to the direction of the temperature gradient developed between the first operational side and the second operational side of the magneto-thermoelectric device.

10. The apparatus of claim 8 further comprising
at least one valve (16) located on a cold side conduit conducting the primary heat transfer fluid (102) into the primary heat exchanger (10);
the at least one control device (17) and the cold side valve communicating to regulate the mass flow rate of coolant (103) through the hot side conduits of the primary heat exchanger.

11. The apparatus of claim 8 wherein the primary fluid is preferably gaseous.

12. The apparatus of claim 11 wherein the secondary fluid is gaseous, liquid or a dual phase fluid.

13. The apparatus of claim 11 wherein the secondary fluid is liquid.

14. A pyrometallurgical vessel (1) comprising
a primary heat exchanger (10) which extracts heat from the vessel (1) and produces a primary heat transfer fluid,
a secondary heat exchanger (12) engagable with the primary heat exchanger (10) of the pyrometallurgical vessel (1) to receive the primary heat transfer fluid (102), the secondary heat exchanger (12) being physically displaced from the pyrometallurgical vessel (1); and
a thermoelectric or magneto-thermoelectric device supported in a fixed position by the secondary heat exchanger, the thermoelectric or magneto-thermoelectric device having a first operational side and a second operational side and having at least one thermoelectric or magneto-thermoelectric element capable of converting a temperature gradient between the first operational side and the second operational side into electrical energy (105); the first operational side being in thermal communication with the primary heat transfer fluid (103) from the primary heat exchanger (10) and the second operational side being in thermal communication with a secondary coolant to establish the temperature differential between the first operational side and the second operational side of the thermoelectric or magneto-thermoelectric device to generate electrical energy (105).

15. The apparatus of claim 14 wherein
the pyrometallurgical vessel is surrounded by a magnetic field generated from input operating electrical power to the pyrometallurgical vessel, the magnetic field having a maximum principal direction component, and
the secondary heat exchanger supports at least the magneto-thermoelectric device so the maximum principal magnetic field component is positioned normally to the direction of the temperature gradient developed between the first operational side and the second operational side of the magneto-thermoelectric device.
